(19) United States
(12) Patent Application Publication
(10) Pub. No.: US 2004/0070419 A1
(43) Pub. Date: Apr. 15, 2004

(54) Semiconductor integrated circuit

(76) Inventors: Masashi Hirano, Tokyo (JP); Yasuhito Itaka, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/357,218

(22) Filed: Feb. 4, 2003

(30) Foreign Application Priority Data
Oct. 10, 2002 (JP) 2002-297568

(51) Int. Cl. H03K 19/00

(52) U.S. Cl. 326/16

(57) ABSTRACT

A semiconductor integrated circuit is disclosed, which comprises a pre-charge type dynamic circuit, a static circuit which realizes the same logic as the dynamic circuit, a selection circuit which is connected to an input section of each of the dynamic circuit and the static circuit, a control circuit which controls the selection circuit to select either the dynamic circuit or the static circuit at the time of testing a semiconductor chip.

### CROSS-REFERENCE TO RELATED APPLICATIONS

This application is based upon and claims the benefit of priority from the prior Japanese Patent Application No. 2002-297568, filed Oct. 10, 2002, the entire contents of which are incorporated herein by reference.

### BACKGROUND OF THE INVENTION

1. Field of the Invention

The present invention relates to a semiconductor integrated circuit (LSI), particularly to a circuit technology to suppress electric power consumption, which is applied to, for example, a high-speed micro processor, logic in memory LSI, or the like.

2. Description of the Related Art

A semiconductor integrated circuit is basically divided into a dynamic circuit and a static circuit. In general, the dynamic circuit operates at high speed. However, in a case where channel-leaks increase due to variations in manufacturing process of LSIs, there is a problem in that the dynamic circuit malfunctions or the operation is unstable.

FIG. 10 shows an OR-circuit of four inputs as an example of the dynamic circuit.

In this circuit, a keeper circuit KP is connected to a dynamic node A of a domino circuit of four inputs.

In a pre-charging period, the dynamic node A is pre-charged to “1” level (“H” level). In an evaluation period after the pre-charge period, if all inputs are at “0” and the dynamic node A is at “1” level, then the dynamic circuit operates properly. However, the dynamic circuit may malfunction because the electric potential of the dynamic node A may decrease due to a channel leak current. To prevent the malfunction, the keeper circuit KP operates so as to prevent the electric potential from decreasing.

In the four inputs OR-circuit, if the size of the transistors (MOSFETs) of the keeper circuit KP is too large, the domino circuit operates slowly. On the contrary, if the size of the transistors of the keeper circuit KP is too small, a problem arises in that the domino circuit may malfunction due to a channel leak.

Incidentally, as a countermeasure against the instability of dynamic circuit operation due to processes variation, known is a technology to stabilize the operation by providing a sense amplifier circuit in double scheme. (For example, Fujisawa et al, “A Dual-Phase-Controlled Dynamic Latched Amplifier for High-Speed and Low-Power DRAMs, IEEE JSSCC Vol. 36, No. 7, July 2001 pp1120-1126).

FIG. 11 shows a circuit in which a sense amplifier circuit is provided in double scheme in a DRAM disclosed in the bulletin as cited above.

In the circuit shown in FIG. 11, two sense amplifiers, i.e., a first sense amplifier (1st-phase DDL amp.) 91 and a second sense amplifier (2nd- phase DDL amp.) 92, are provided and operated at the different timing.

In this case, a sense enable signal EN1 for controlling the first sense amplifier 91 is transmitted faster than a sense enable signal EN2 for controlling the second sense amplifier 92. Then, an output signal OUT1 of the first sense amplifier 91 is outputted faster than an output signal OUT2 of the second sense amplifier 92 which starts an operation in accordance with the sense enable signal EN2. The output signal OUT2 of the second sense amplifier 92 and the output signal OUT1 of the first sense amplifier 91 are compared to each other by an error correcting selector 93. When an error is detected in data, it is corrected.

That is, when a threshold voltage of the transistors is decreased due to process variation, the output of the sense amplifier circuit is corrected by the output signal OUT2.

On the other hand, the static circuit operates stably against the process variation in manufacturing. However, the operation speed of the static circuit is lower than dynamic circuits. If a multi-input circuit is realized so as to increase the operation speed of the static circuit, a large number of MOSFETs are connected in a cascade scheme. In such a circuit, the threshold voltage of the MOSFETs increases because an electric potential across a source and substrate of the MOSFETs is applied in the reverse direction. However, the electric potential difference across the source and drain of the MOSFETs becomes small.

For this reason, the multi-input circuit of the static circuit is often configured in a manner that small input circuits are connected in a multistage way. For example, as shown in FIG. 12, a four input circuit is often realized by combining two two-input input stage circuits 101 and a two-input output stage circuit 102.

Meanwhile, as we can see on a microprocessor etc., an LSI that operates at very high-speed, in which the operation frequency becomes several GHz, has been manufactured in these days. However, in proportion to the high-speed operation frequency, the electric power consumption increases, which is a serious problem.

As one of the countermeasures, there has been developed a technology to reduce the electric power consumption by using clock control method. In this technology, for a process that does not need the high-speed operation so much, the frequency of the clock signal is set low to suppress the electric power consumption.

In a logic LSI, particularly in a arithmetic logic unit, in order to increase the operation speed of the circuits, a circuit that operates in synchronization with the clock signal, e.g., the dynamic circuit, is often used instead of the static circuit. Hence, in the LSI, which is occupied with the circuits that operate in synchronization with the clock signal, the electric power consumption of the circuits connected to the clock signal increases in the entire electric power consumption. For this reason, even if the electric power consumption is reduced with use of the aforementioned conventional clock control method, it has been very difficult to satisfactorily suppress the electric power consumption.

As described above, in the high-speed operating logic LSI, a problem lies in that, even if the electric power consumption is reduced with use of the aforementioned conventional clock control method, it has been very difficult to satisfactorily suppress the electric power consumption.

### BRIEF SUMMARY OF THE INVENTION

According to an aspect of the present invention, there is provided a semiconductor integrated circuit comprising a pre-charge type dynamic circuit; a static circuit which realizes the same logic as the dynamic circuit; a selection circuit which is connected to an input section of each of the dynamic circuit and the static circuit; a control circuit which controls the selection circuit to select either the dynamic circuit or the static circuit at the time of testing a semiconductor chip.

According to another aspect of the present invention, there is provided a semiconductor integrated circuit comprising a clock control circuit which receives a clock signal and a low power-consumption mode control signal, outputs the clock signal retaining a logic level of the clock signal at the time when the power-consumption mode control signal is in an inactive state, and fixes the logic level of the clock signal at the time when the low power-consumption mode control signal is in an active state; and a logic circuit which receives an output signal of the clock control circuit as a control signal, and, when the control signal is the clock signal, operates in synchronization with the clock signal.

### BRIEF DESCRIPTION OF THE DRAWINGS

FIG. 1 is a circuit diagram showing a part of a logic LSI according to a first embodiment of the present invention;

FIG. 2 is a graph showing an example of the relation between a threshold voltage Vth corresponding to process variation of the logic LSI and operation speed;

FIG. 3 is a circuit diagram showing an example of a leak monitor circuit used for detecting process variation in a control circuit shown in FIG. 1;

FIG. 4 is a circuit diagram showing a part of a logic LSI according to a second embodiment of the present invention;

FIG. 5 is a timing diagram showing a signal waveform in a high-speed operation of a logic circuit in FIG. 4;

FIG. 6 is a timing diagram showing a signal waveform in a low power-consumption operation of the logic circuit in FIG. 4;

FIG. 7 is a circuit diagram showing a part of a logic LSI according to a third embodiment of the present invention;

FIG. 8 is a circuit diagram showing a part of a logic LSI according to a modification of the second embodiment as shown in FIG. 4 of the present invention;

FIG. 9 is a circuit diagram showing a part of a logic LSI according to a modification of the third embodiment as shown in FIG. 7 of the present invention;

FIG. 10 is a circuit diagram showing a multi-input OR circuit as an example of a dynamic circuit;

FIG. 11 is a circuit diagram showing an example of a circuit in which a sense amplifier circuit is provided in double scheme so as to stabilize an operation of the dynamic circuit in a DRAM; and

FIG. 12 is a circuit diagram showing an example of a logic circuit provided by combining small input circuits in a multi-stage as a static circuit.

### DETAILED DESCRIPTION OF THE INVENTION

Embodiments of the present invention now will be described in detail with reference to accompanying drawings.

### First Embodiment

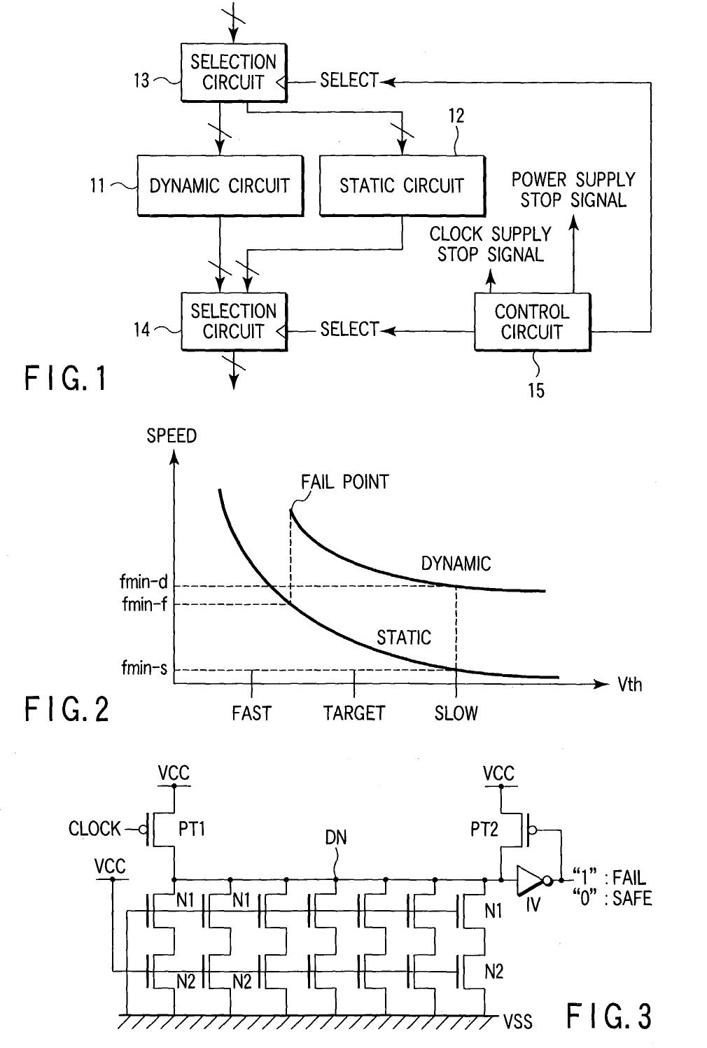

FIG. 1 shows a part of a logic LSI according to a first embodiment of the invention.

A circuit shown in FIG. 1 is applied to a memory peripheral circuit including a path critical with regard to operation speed in a logic in memory LSI, for example.

A control circuit 15 generates an input-side select signal Select and an output-side select signal Select. The control circuit 15 also generates a power supply stop signal and a clock signal stop signal. A selection circuit 13 receives an input signal. The selection circuit 13 also receives the input-side selection signal Select from the control circuit 15 to select a dynamic circuit 11 or a static circuit 12 according to the input-side selection signal Select from the control circuit 15, and outputs the received signal to the selected circuit. Output signals of the dynamic circuit 11 and the static circuit 12 are inputted to a selection circuit 14. The selection circuit 14 receives the output-side selection signal Select from the control circuit 15 to select the dynamic circuit 11 or the static circuit 12 according to the output-side selection signal Select from the control circuit 15, and outputs the output signal of the selected circuit.

The dynamic circuit 11 and the static circuit 12 may be a small scale circuit such as a standard cell, or may be a large scale circuit block such as an ALU (arithmetic logic unit).

FIG. 2 is a graph showing an example of the relation between a threshold voltage Vth corresponding to process variation and an operation speed of the logic LSI shown in FIG. 1.

As shown in FIG. 2, when the threshold voltage Vth of a transistor (MOSFET) is increased due to variation of a manufacturing process of the logic LSI (the threshold voltage Vth shifts toward the “Slow” side in the abscissa in FIG. 2), the operation speed of the dynamic circuit slightly lowers. However, the operation speed of the static circuit greatly lowers. Therefore, in this case, it is preferable to operate the high-speed dynamic circuit 11 at the normal use of the logic LSI but not to operate the static circuit 12.

On the contrary to the above, when the threshold voltage Vth of the transistor (MOSFET) is decreased due to the variation of a manufacturing process of the logic LSI (the threshold voltage Vth shifts toward the “Fast” side in the abscissa in FIG. 2), the operation speed of the dynamic circuit reaches the fail point, and a malfunction occurs. In this case, the operation speed of the transistor itself is sufficiently high, so that even the low-speed static circuit can be operated relatively at high-speed. Therefore, in this case, at the normal use of the logic LSI, it is preferable to operate relatively high-speed static circuit 12 but not to operate the dynamic circuit 11.

By controlling in the manner as described above, the lowest operation speed for the LSI chip becomes the speed (fmin-d) of the dynamic circuit at the time when the threshold voltage Vth changes to the slow side or the speed (fmin-f) of the static circuit under the condition that a malfunction occurs in the dynamic circuit, whichever is lower. Besides, the lowest operation speed for the LSI chip is higher than the speed (fmin-s) of the static circuit at the time when the threshold voltage Vth moves toward the slow side.

In order to detect process variation in the control circuit 15 shown in FIG. 1, it is possible to use a leak monitor circuit. The leak monitor circuit monitors a leak current in testing the LSI chip. When the leak current is large, the leak monitor circuit determines whether or not the dynamic circuit 11 operates under all the conditions. According to the determined result, the leak monitor circuit controls the selection circuits 13 and 14 to select the dynamic circuit 11 or the static circuit 12.

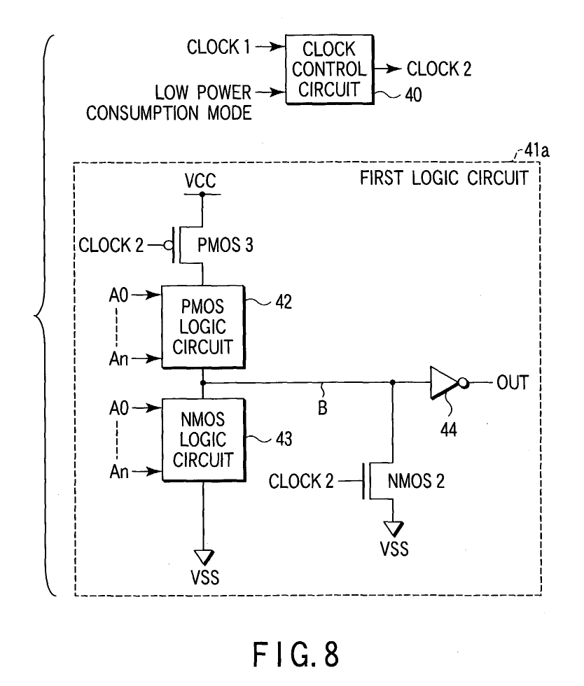

In this case, the leak monitor circuit is configured to be a circuit more unstable than a dynamic circuit, of dynamic circuits to which the selection method according to the invention is applied, whose operation is most unstable. As an example, the number or size of an input transistor is larger than the multi-input OR circuit described with reference to FIG. 8, or the size of the transistor of the keeper circuit is small or the gate length is short.

In the control circuit 15, when the leak current increases due to process variation and thus the operation of the dynamic circuit 11 becomes unstable, the static circuit 12 is selected. On the other hand, when the leak current is small and thus the dynamic circuit 11 operates stably, the dynamic circuit 11 is selected. Thus, it is possible to increase the operating frequency of the logic LSI.

In this case, depending on the result of monitoring the leak current in testing the LSI chip, it is determined to select the dynamic circuit 11 or the static circuit 12. In the normal mode, the logic level of the output of the control circuit 15 is fixed to a selecting logic level by which the selection of the circuits is carried out in accordance with the determination.

Incidentally, in order to reduce wasteful power consumption and reduce the electric power consumption in operating, it is preferable that the selected circuit, which is selected from the dynamic circuit 11 and the static circuit 12 is operated, on the other hand the non-selected circuit is not operated. For this end, as a concrete example, a clock supply stop signal is generated from the control circuit 15 to stop supplying the clock signal to the non-selected circuit.

As another concrete example for controlling not to operate the non-selected circuit, an electric power supply stop signal is generated from the control circuit 15, and thus an electric power supply to the non-selected circuit is stopped. In such a case, it is also possible to reduce the electric power consumption in a stand-by mode.

FIG. 3 shows an example of a leak monitor circuit used for detecting process variation in the control circuit 15 shown in FIG. 1.

The leak monitor circuit is a pre-charge type seven-input OR circuit. A pre-charging PMOS transistor PT1, which is controlled by a clock signal CLOCK, is connected between a power supply (VCC) node and a dynamic node DN. Seven series circuits, each of which is connected to series-connected two NMOS transistors N1 and N2, are connected in parallel to each other between the node DN and grounding (VSS) node. Further, an inverter circuit IV is connected between the node DN and an output node. A PMOS transistor PT2 as a keeper circuit to whose gate an output of the inverter circuit IV is fed back, is connected between the VCC node and the node DN.

The gate of the NMOS transistor N1 in each of the series circuits is connected in common to the VSS node, and the gate of the NMOS transistor N2 in each of the series circuits is connected in common to the VCC node.

During a pre-charge period, the pre-charging transistor PT1 becomes ON, and the dynamic node DN is pre-charged to the VCC. At this time, the logic level of the output node becomes “0”, which shows a Safe state.

The pre-charge period ends and then an evaluation period (stand-by operation) starts. After that, when the electric potential of the dynamic node DN decreases lower than a certain value due to the channel leak current of the transistors N1 and N2 of the seven series circuits, the logic level of the output node becomes “1”, and shows a Fail state.

During the period when the output of the leak monitor circuit is logic “0”, the dynamic circuit 11 shown in FIG. 1 operates properly. Therefore, the dynamic circuit 11 is selected and operated. On the other hand, when the output of the leak monitor circuit becomes logic “1”, it is in the Fail state in which an error has occurred in the leak monitor circuit. Therefore, it is controlled to operate the static circuit 12 instead of the dynamic circuit 11 shown in FIG. 1.

As described above, in the logic LSI according to the first embodiment, the logic circuit is of double scheme and comprises two circuits, i.e. the dynamic circuit 11 and the static circuit 12, both performing the same logic operation. By selecting one of the circuits, which is higher in operation speed than the other, against the variation of LSI manufacturing process, it is possible to suppress variation of the operation frequency due to the process variation, and increase the maximum operation frequency.

Incidentally, in the present embodiment, when the leak current is large due to the process variation and thus the operation of the dynamic circuit 11 is unstable, it is controlled to select the static circuit 12. However, it is also possible that, when the operation of the dynamic circuit 11 deteriorates due to the increase of the temperature in the use state and the dynamic circuit 11 cannot be operated any more, the control is changed to select the static circuit 12.

Further, in addition to the control to select the dynamic circuit 11 or the static circuit 12, it is possible to change or switch power voltage of the operation power supply so as to increase the operation speed.

### Second Embodiment

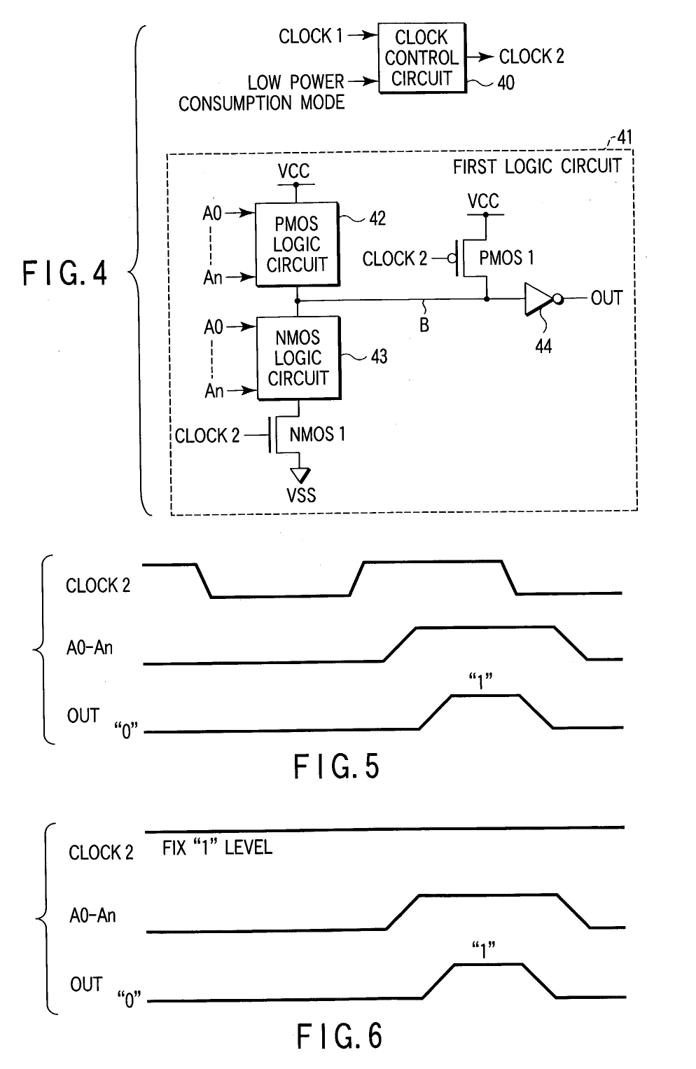

FIG. 4 shows a part of the logic LSI according to a second embodiment of the present invention.

In FIG. 4, a first logic circuit 41 is configured in that a PMOS logic circuit 42, an NMOS logic circuit 43, and an NMOS transistor NMOS1 are connected in series between the power supply node and a grounding node.

The PMOS logic circuit 42 and the NMOS logic circuit 43 constitute a multi-input NAND circuit, for example. In the NAND circuit, the PMOS logic circuit 42 includes a plurality of PMOS transistors, not shown, which are connected in parallel to each other and to whose gates a plurality of signals A0 to An are inputted, respectively, and the NMOS logic circuit 43 includes a plurality of NMOS transistors, not shown, which are connected in series to each other and to whose gates a plurality of signals A0 to An are inputted, respectively. A clock signal CLOCK 2 is inputted to the gate of the NMOS transistor NMOS1.

An intermediate node B, to which the PMOS logic circuit 42 and the NMOS logic circuit 43 are connected, is connected to an output node Out via an inverter circuit 44. Between the power supply node and the intermediate node B, the PMOS transistor PMOS1 is connected. The clock signal CLOCK 2 is inputted to the gate of the PMOS transistor PMOS1.

A clock signal CLOCK 1 and a low power-consumption mode control signal are inputted to a clock control circuit 40, and the circuit 40 outputs the clock signal CLOCK 2. In this case, when the low power-consumption mode control signal is in the inactive state, the clock signal 1 retaining the logic level is outputted as the clock signal CLOCK 2. On the contrary, when the low power-consumption mode control signal is in the active state (low power-consumption mode), the clock signal CLOCK 2 is fixed at logic “1” level.

In the circuit shown in FIG. 4, the first logic circuit 41 is selectively set to the normal high-speed operation state or to the electric power low consumption state by the clock signal CLOCK 2 inputted to the first logic circuit 41, the operation thereof will be described below with reference to FIG. 5.

FIG. 5 shows a timing diagram in a normal high-speed operation of the first logic circuit 41 shown in FIG. 4. In a normal high-speed operation, the clock signal CLOCK 1 with the current logic level is supplied to the first logic circuit 41 as the clock signal CLOCK 2, and the first logic circuit 41 operates in synchronization with the clock signal CLOCK 2.

In this case, when the clock signal 2 is at logic “0” level, the operation is in a pre-charge period, and the PMOS transistor PMOS1 is turned on and the NMOS transistor NMOS1 is turned off, so as to set the logic level of the node B to logic “1” level.

On the contrary to the above, when the clock signal CLOCK 2 is at logic “1” level, the operation is in an evaluation period, and the PMOS transistor PMOS1 is turned off and the NMOS transistor NMOS1 is turned on. Then, in accordance with the signal A0 to An, the PMOS logic circuit 42 is turned on so as to hold the node B at logic “1” level, or the NMOS logic circuit 43 is turned on so as to invert the logic level of the node B to logic “0” level.

In the circuit shown in FIG. 4, the state transition of the logic level of the clock signal in the first logic circuit 41 is one way (transition direction at the node B is logic “1” level→logic “0” level). Therefore, by enlarging the size Wn of the transistors (not shown) of the NMOS logic circuit 43 and reducing the size Wp of the transistors (not shown) of the PMOS logic circuit 42, that is, by reducing Wp/Wn, the circuit shown in FIG. 4 operates at high-speed as in a dynamic circuit.

In addition, the node B of the first logic circuit 41 will never be floating by the operations of the PMOS logic circuit 42 and the NMOS logic circuit 43. Thus, the first logic circuit 41 is strong against noise in comparison with a dynamic circuit.

FIG. 6 shows a timing diagram of the first logic circuit 41 shown in FIG. 4 at the time when the first logic circuit 41 does not need operate at high-speed so much and thus operates in low power-consumption.

In this operation, the clock signal CLOCK 2 supplied to the first logic circuit 41 is fixed at “1” level. At this time, in the first logic circuit 41, the PMOS transistor PMOS1 is turned off and the NMOS transistor NMOS1 is turned on, and thus the PMOS logic circuit 42 and the NMOS logic circuit 43 are operated as a static circuit.

In addition, since the size Wp of the transistors (not shown) of the PMOS logic circuit 42 as described above is small, the time for transition of the node B from logic “0” level to logic “1” level is long. However, the operation frequency is originally low in the electric power low consumption operating, so that it does not matter.

Further, since the clock signal CLOCK 2 is fixed to “1” level, then the electric power consumption for charging and discharging by the PMOS transistor PMOS1 and the NMOS transistor NMOS1, in which the clock signal CLOCK 2 is inputted to the gate thereof, does not occur. Furthermore, the electric power consumption of the wiring conductor of the clock signal CLOCK 2 and the clock control circuit 40 in the charging and discharging is not generated. Thus, in a case where a process does not need high-speed operation so much, the low power-consumption mode is effective.

As described above, in the logic LSI according to the second embodiment, slight parts of hardware such as the clock control circuit 40, by which the logic level of the clock signal can be fixed in electric power low-consumption operation, is added. Then, it becomes possible to suppress variations of the operation frequency due to variation of manufacturing process, and reduce electric power consumption more than a logic circuit using the conventional clock control method.

### Third Embodiment

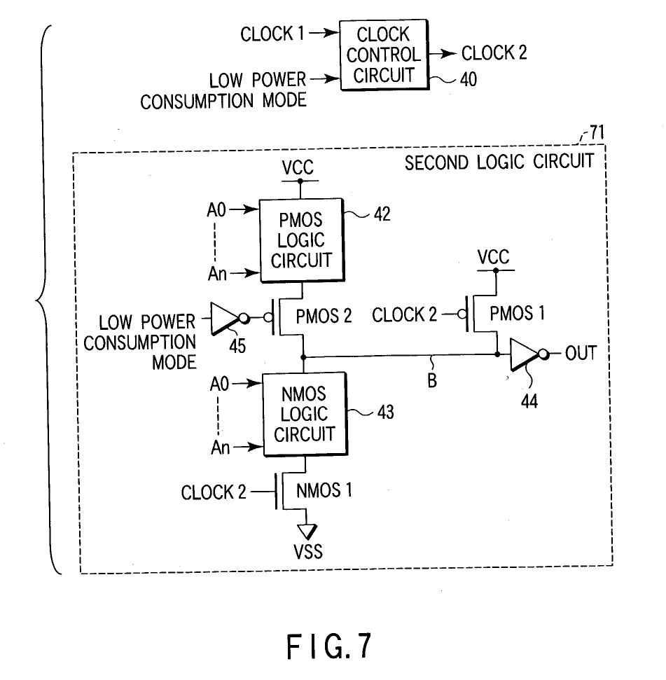

FIG. 7 shows a part of the logic LSI according to a third embodiment of the invention.

In the circuit shown in FIG. 7, the first logic circuit 41 in the circuit shown in FIG. 4 according to the aforementioned second embodiment is changed to a second logic circuit 71. In comparison with the first logic circuit 41, the second logic circuit 71 is different in that a PMOS transistor PMOS2 is inserted between the PMOS logic circuit 42 and the node B. A signal provided by inverting the low power-consumption mode signal by an inverter circuit 45 is inputted to the gate of the PMOS transistor PMOS2. The other parts or portions are the same as in the first logic circuit 41 and thus the same numerals or characters are used.

According to the second logic circuit 71, in the evaluation period of the normal high-speed operation, the PMOS transistor PMOS 2 is turned off, and a capacitive load on the PMOS logic circuit 42 side is electrically separated from the node B. Therefore, the capacitive load of the node B decreases and thus the operation can be carried out at more high-speed than in the second embodiment described above.

In the electric power low-consumption operation, the PMOS transistor PMOS2 is turned on, so that similar or the same operation and advantages as in the second embodiment can be obtained.

Incidentally, in the first logic circuit 41 according to the aforementioned second embodiment and the second logic circuit 71 according to the third embodiment, when the operation relation between the PMOS logic circuit 42 and the NMOS logic circuit 43 is reversed (for example, if a NOR circuit is constructed), it functions equivalently to the embodiments described above.

### Modification of Second Embodiment

FIG. 8 is a circuit diagram showing a part of a logic LSI according to a modification example of the second embodiment as shown in FIG. 4 of the present invention;

As shown in the logic circuit 41a in FIG. 8, a PMOS transistor PMOS3, to whose gate the clock signal CLOCK2 is inputted, is inserted between the VCC node and the PMOS logic circuit 42, instead of the NMOS transistor NMOS1 in the first logic circuit 41. Furthermore, an NMOS transistor NMOS2 for discharge operation, to whose gate the clock signal CLOCK2 is inputted, is inserted between the intermediate node B and the VSS node, instead of the PMOS transistor PMOS1 for the pre-charge operation. Also in this modification, the similar operation as in the second embodiment can be obtained.

### Modification of Third embodiment

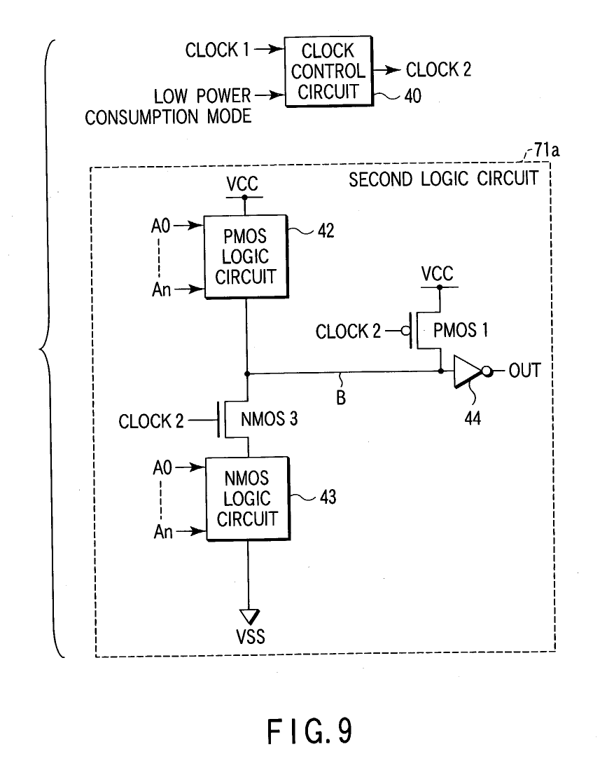

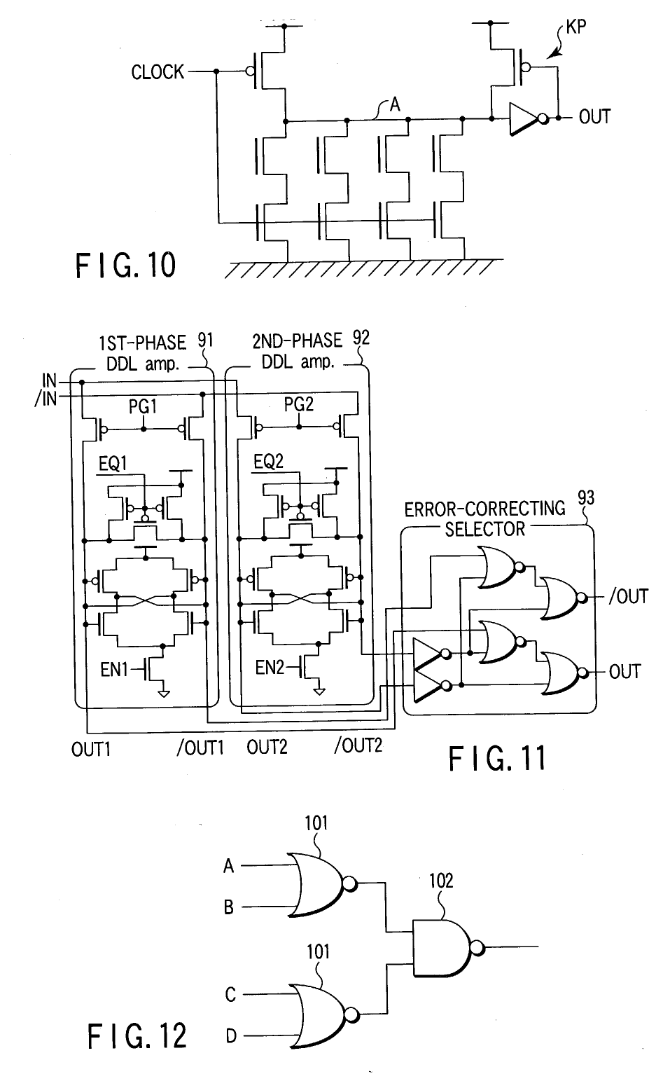

FIG. 9 is a circuit diagram showing a part of a logic LSI according to a modification example of the third embodiment as shown in FIG. 7 of the present invention;

As shown in the logic circuit 71a in FIG. 9, an NMOS transistor NMOS3, to whose gate the clock signal CLOCK2 is inputted, is inserted between the intermediate node B and the NMOS logic circuit 43, instead of the PMOS transistor PMOS2 inserted between the PMOS logic circuit 42 and the intermediate node B.

What is claimed is:

1. A semiconductor integrated circuit comprising:
a pre-charge type dynamic circuit;
a static circuit which realizes the same logic as the dynamic circuit;
a selection circuit which is connected to an input section of each of the dynamic circuit and the static circuit;
a control circuit which controls the selection circuit to select either the dynamic circuit or the static circuit at the time of testing a semiconductor chip.

2. The semiconductor integrated circuit according to claim 1, wherein the control circuit comprises a leak monitor circuit which monitors a current corresponding to a leak current of the dynamic circuit, and controls the selection circuit in accordance with a monitor result of the leak monitor circuit.

3. The semiconductor integrated circuit according to claim 1, wherein, at the time of normal use of the semiconductor chip, the control circuit stops supplying a clock signal to one of the dynamic circuit and static circuit that is not selected to reduce an electric power consumption in an operating period.

4. The semiconductor integrated circuit according to claim 2, wherein, at the time of normal use of the semiconductor chip, the control circuit stops supplying a clock signal to one of the dynamic circuit and static circuit that is not selected to reduce an electric power consumption in an operating period.

5. The semiconductor integrated circuit according to claim 1, wherein, at the time of normal use of the semiconductor chip, the control circuit stops supplying a power supply to one of the dynamic circuit and static circuit that is not selected to reduce an electric power consumption in a stand-by period.

6. The semiconductor integrated circuit according to claim 2, wherein, at the time of normal use of the semiconductor chip, the control circuit stops supplying a power supply to one of the dynamic circuit and static circuit that is not selected to reduce an electric power consumption in a stand-by period.

7. A semiconductor integrated circuit comprising:
a clock control circuit which receives a clock signal and a low power-consumption mode control signal, outputs the clock signal retaining a logic level of the clock signal at the time when the low power-consumption mode control signal is in an inactive state, and fixes the logic level of the clock signal at the time when the low power-consumption mode control signal is in an active state; and
a logic circuit which receives an output signal of the clock control circuit as a control signal, and, when the control signal is the clock signal, operates in synchronization with the clock signal.

8. The semiconductor integrated circuit according to claim 7, wherein the logic circuit comprises:
a PMOS logic and an NMOS logic which are connected in series between a power supply node and a grounding node;
an NMOS transistor which is inserted between the NMOS logic and the grounding node, and to whose gate the clock signal is inputted; and
a pre-charging PMOS transistor which is connected between an intermediate node to which the PMOS logic and the NMOS logic are connected and the power supply node, and to whose gate the control signal is inputted.

9. The semiconductor integrated circuit according to claim 8, wherein the logic circuit comprises a PMOS transistor inserted between the PMOS logic and the intermediate node, and to whose gate the low power-consumption MODE control signal is inputted.

10. The semiconductor integrated circuit according to claim 8, wherein the PMOS logic and the NMOS logic constitute a NAND circuit, the PMOS logic circuit includes a plural of PMOS transistors which are connected in parallel to each other and to whose gates a plurality of signals are inputted, respectively, and the NMOS logic circuit includes a plural of NMOS transistors which are connected in series to each other and to whose gates a plurality of signals are inputted, respectively.

11. The semiconductor integrated circuit according to claim 9, wherein the PMOS logic and the NMOS logic constitutes a NAND circuit, the PMOS logic circuit includes a plural of PMOS transistors which are connected in parallel to each other and to whose gates a plurality of signals are inputted, respectively, and the NMOS logic circuit includes a plural of NMOS transistors which are connected in series to each other and to whose gates a plurality of signals are inputted, respectively.

12. The semiconductor integrated circuit according to claim 7, wherein the logic circuit comprises:
a PMOS logic and an NMOS logic which are connected in series between a power supply node and a grounding node;
a PMOS transistor which is inserted between the power supply node and the PMOS logic, and to whose gate the control signal is inputted; and
a discharging PMOS transistor which is connected between an intermediate node to which the PMOS logic and the NMOS logic are connected and the power supply node, and to whose gate the control signal is inputted.

13. The semiconductor integrated circuit according to claim 12, wherein the logic circuit comprises an NMOS transistor inserted between the intermediate node and the NMOS logic, and to whose gate the low power-consumption MODE control signal is inputted.
